(19) United States
(12) Patent Application Publication
(10) Pub. No.: US 2023/0297730 A1
(43) Pub. Date: Sep. 21, 2023

(54) METHOD AND SYSTEM FOR GENERATING AN EXPLODED LAYOUT OF CAD MODELS IN A 3D GRAPHIC ENVIRONMENT

(71) Applicant: Siemens Industry Software Ltd., Tel Aviv (IL)

(72) Inventor: Nir Sagi, Ramat Gan (IL)

(21) Appl. No.: 18/041,712

(22) PCT Filed: Aug. 18, 2020
(86) PCT No.: PCT/IB2020/057758

§ 371 Date: Feb. 15, 2023

(51) Int. Cl. G06F 30/12

(52) U.S. Cl. CPC G06F 30/12

(57) ABSTRACT

Systems and methods for generating an exploded layout of a CAD model in a 3D graphic environment include selection of a 3D user's viewpoint according to which explosion to be performed is defined and input. Hierarchies in the model are also identified. The model is then exploded, through a direct interaction with the model representation on the graphic viewer, into a 2D configuration of components. One or more components belonging to a lower hierarchical level are individually selected, on the graphic viewer, for being in turn exploded to a further lower hierarchical level. The operation of exploding a component is repeated for the selected component(s), and then for selected components visible as a result of each explosion step, until reaching a lowest hierarchical level.

### TECHNICAL FIELD

The present disclosure is directed, in general, to computer-aided design, visualization and manufacturing (“CAD”) systems, product lifecycle management (“PLM”) systems, product data management (“PDM”) systems, and similar systems, that manage data for products and other items (collectively, “Product Data Management” systems or PDM systems). More specifically, the disclosure is directed to production environment simulation.

For the sake of simplicity and without any limiting purpose, all such systems will be referred to as “CAD systems” or “computer graphics systems” in the following description.

### BACKGROUND OF THE DISCLOSURE

When planning a manufacturing assembly procedure for a product in a computer graphics software, it is crucial for the user to view and interact with the CAD models in a visible, user friendly and intuitive manner. Functions such as hide/view parts and transparency, which allow the user to view internal and hidden parts within the 3D assembly structure, and in particular the “explode” functions allows the user to view the whole assembly in a sphere like shape without the need to blank out any parts, are of primary interest for such a user-model interaction.

Tasks connected with planning the assembly process and authoring work instructions commonly rely on textual information, items list, and visuals of the actual product (when available), because executing them via interacting directly with the 3D models lacks visibility, is not intuitive and is subject to human errors in a typical user interface of a computer graphics software. With such a way of operating, the assembly structure is usually displayed next to the graphic viewer and is directly linked (1:1) with the 3D objects which allows the user to identify parts by their textual information within the assembly, highlight them and understand their relevancy (to sub-assemblies) according to the structure's hierarchy.

This manner of operating is rather complex and scarcely efficient. Moreover, it does not allow fully exploiting the CAD models throughout the whole lifecycle of a product, in particular during later stages such as production engineering and production execution.

Other solutions for providing the users of CAD systems with the possibility of creating exploded views a CAD model thereof. Examples are disclosed in U.S. Pat. No. 6,295,063 B1 and U.S. Pat. No. 7,710,420 B2.

U.S. Pat. No. 6,295,063 B1 proposes a method where the exploded view is generated automatically, based on assembly considerations, and the explosion is applied to all parts within an assembly structure. The method allows a limited interaction of the user with the system implementing the method in respect of the choice of items to be exploded and the level of explosion. U.S. Pat. No. 7,710,420 B2 provides a method for navigating among CAD objects stored in a database and allows acting on the objects displayed on a graphical user interface. Yet, it is focused on the database structure that comprises the links between the objects and on the “weight” of an object, i.e. a parameter linked to the number of descendants of the object, rather than on allowing graphical visibility of the exploded object, at any hierarchical level, to the user.

Therefore, improved techniques are desirable for generating an exploded layout of CAD models, which allows a strong interaction of the user with the system and provides a graphical visibility of an object being exploded to the user.

### SUMMARY OF THE DISCLOSURE

Various disclosed embodiments include methods and corresponding systems and computer readable mediums for generating an exploded layout of a CAD model in a 3D graphic environment. A method includes determining and inputting to the implementing data processing system a 3D user's viewpoint according to which explosion is to be performed. Hierarchies in the model are also identified. The model is then exploded, through a direct interaction with the model representation on a graphic viewer of the data processing system, into a 2D configuration of components. The method further includes individually selecting, on the graphic viewer, one or more components belonging to a lower hierarchical level for being in turn exploded to a further lower hierarchical level. The or each component so selected is exploded, through a direct interaction with the component representation on the graphic viewer; into a respective 2D configuration of components, and the operations of individually selecting, on the graphic viewer, one or more components belonging to a lower hierarchical level and exploding a component are repeated for selected components until reaching a lowest hierarchical level of interest.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following description taken in conjunction with the accompanying drawings, wherein like numbers designate like objects, and in which:

FIG. 1 illustrates a block diagram of a data processing system in which an embodiment can be implemented;

FIG. 2 illustrates a CAD 3D model before explosion as displayed in the graphical viewer, together with textual information about the assembly structure;

FIG. 3 is a view similar to FIG. 2, illustrating in the graphical viewer an exploded view of the model shown in FIG. 2;

FIG. 4 is a view similar to FIGS. 2 and 3, illustrating in the graphical viewer an unexploded view of a sub-assembly and showing also the textual information about the sub-assembly structure;

FIG. 5 illustrates a general flow chart of the method.

### DETAILED DESCRIPTION

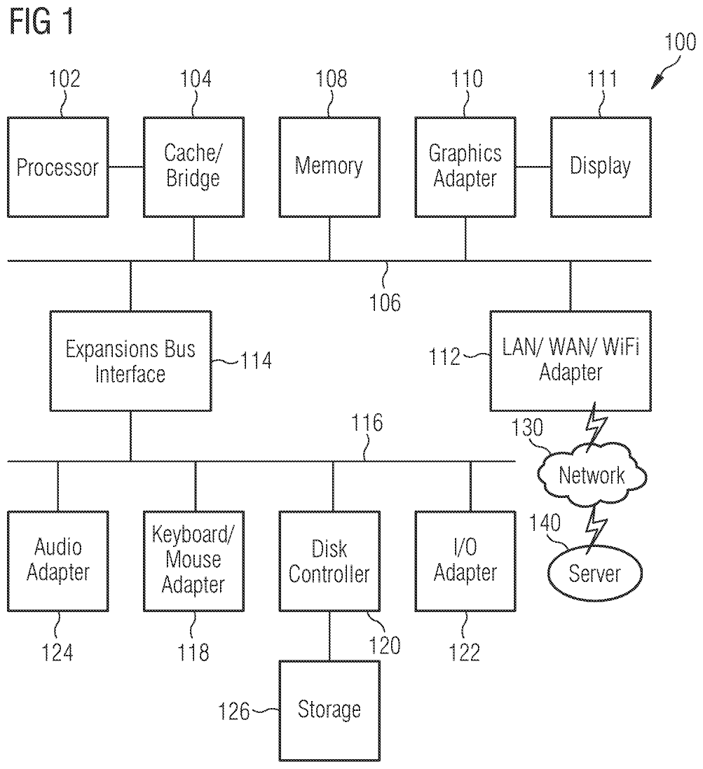

FIGS. 1 through 5, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Embodiments will improve the efficiency of manufacturing process planning and work instructions authoring processes by allowing the user to easily interact with the CAD models, have full control of the visibility of the product and its dependents (sub-assemblies) in relation to its pre-defined structure, enable a method to create visually satisfying work instructions without having a physical product in hands, and position a 3D model-based solution that is flexible and supports rapid changes in the manufacturing process.

By the explosion of the CAD data in reference to the user's viewpoint (which translates to a 2D plane) in a 2D shape (circular) rather than a 3D shape, embodiments improve the user's visibility and understanding of the components in the assembly. Utilizing the CAD assembly hierarchy information allows this method to control the explosion across different sub-assemblies within the CAD. The user can decide where to focus visually, determine sub-assemblies as end items and disregard their components.

Embodiments will improve manufacturing planning offering, specifically in the process planning and work instructions authoring domains. This will impact these domains by easing the authoring process of 3D model-based work instructions and will allow full utilization of the CAD models throughout later stages of the product lifecycle (production engineering and production execution). This method would also serve as basis for 3D interaction in future industrial AR (Augmented Reality) applications.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

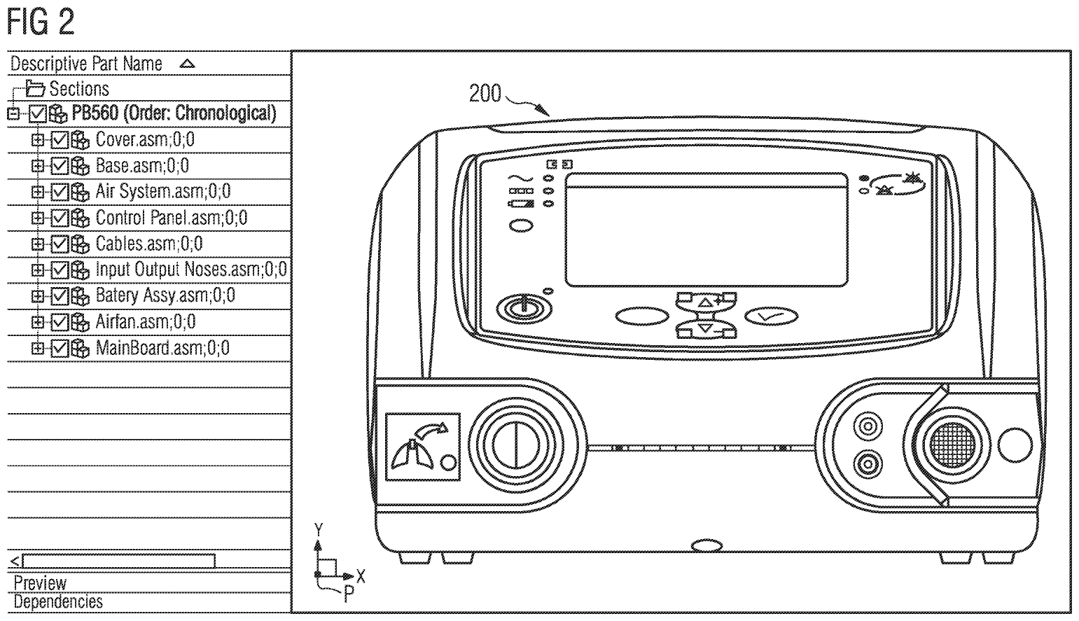

FIGS. 2 to 4 illustrate by way of example the application of the present method to the CAD model of a ventilator type Puritan Bennet™ 560 (in short PB560) manufactured by Medtronic plc, a company having its legal headquarters in Dublin, Ireland, and its operational headquarters in Minneapolis, (Minnesota, USA).

In all such Figures, the right part is the graphic viewer (or graphic user interface) and the left side includes the textual lists of the components. In the graphic viewers of FIGS. 2 to 4, the ventilator has been generally denoted by reference numeral 200, and reference symbol P denotes the user's viewpoint according to which the exploded view will be formed. In conventional manner, symbol “+” in the box aside a sub-assembly name in a list indicates the existence of components at a lower hierarchical level, to be possibly shown in an exploded view.

User's viewpoint P is the origin of the 3D environment and it is determined via pan, zoom and rotate functions, known per se. Usually, such a determination takes place through a camera that allows identifying an exact location. The viewpoint is also known as 3D camera parameters.

Model 200 will be exploded into a 2D image on a plane perpendicular to a vector originating from point P. For the explosion, hierarchies in the 3D model, inherited from the CAD software, are identified and the user will be able to determine both the level at which perform explosion, drilling down from top (the complete ventilator 200) down (sub-assemblies and parts) until a lowest hierarchical level of interest, and also to individually decide for each sub-assembly whether or not it is to be selected for being exploded for assembly planning. In general, a hierarchy adopted is based on manufacturing considerations and it takes e.g. into account that each sub-assembly may be assembled in a different station in the shop floor, or even in a different factory or by an external supplier. FIGS. 2 to 4 report the hierarchies decided by the ventilator's manufacturer just based on manufacturing considerations relevant to the specific object.

In the illustrated example, the level of explosion is one level down from the root item. As to the possibility of deciding whether or not to explode an item, this takes in particular into account the fact that some items can be received already pre-assembled from an external provider, so that there is no interest for the user to explode them in the work instructions. Such items are referred to here as “end items”. For the end items, the 3D CAD detailed to their constituent parts is anyhow available to the user, even if no explosion will take place.

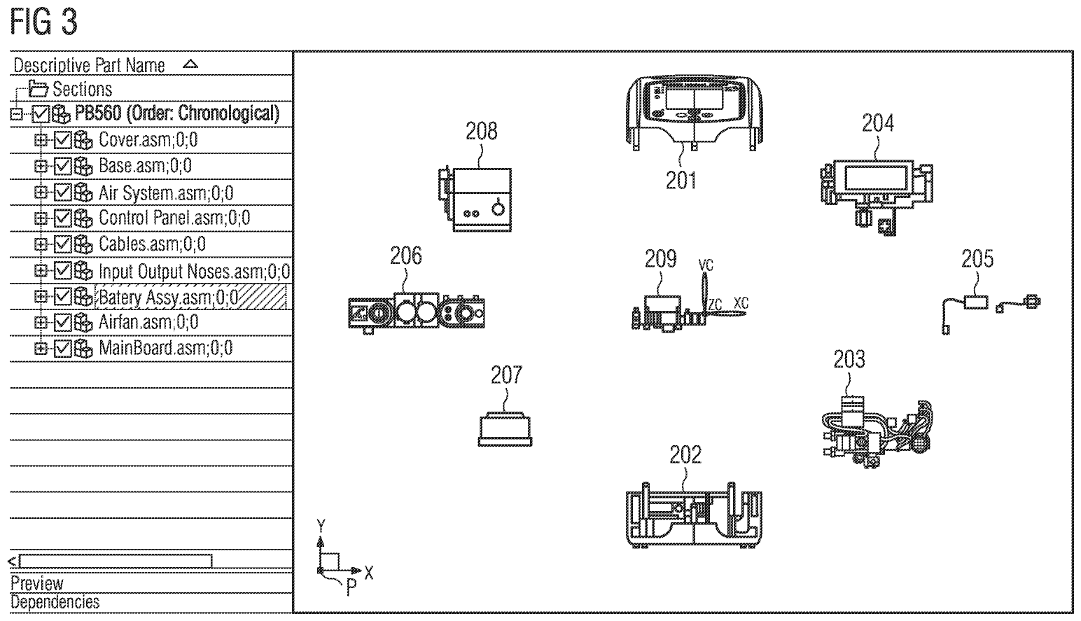

Selection by the user of the completely assembled ventilator 200 in the graphic viewer of FIG. 2 will result in explosion thereof into the first level sub-assemblies listed in the left-side menus of FIGS. 2 and 3. As shown in FIG. 3, the result of the explosion is an image with a substantially circular shape, with a radius across the plane mentioned above (and hence a distance of the plane from point P) such that all parts are situated close to one another, without overlapping, and are all visible to the user. In the exemplary case of ventilator PB560, the first level sub-assemblies are cover 201, base 202, air system 203, control panel 204, cables 205, input-output noses 206, battery assembly 207, air fan 208 and mainboard 209.

One or more of sub-assemblies 201-209 can be individually addressed (i.e. selected on the graphic viewer by clicking in the respective image) for being exploded into its (their) lower level components. When the user selects an element on the viewer, the software will start a searching mechanism that leads to the nearest parent that was not exploded yet by the user, explodes such parent and marks the relevant node as exploded. In this way, the method takes track of the current status of the explosion of each part.

Up to this phase of the procedure, the whole ventilator 200 is being considered, and all components are marked as selected in the lists of components in the left sides of FIGS. 2 and 3 just to reference to the complete sub-assembly. Moreover, in the list of FIG. 3, the item “battery assembly” is highlighted as an end item, so that its parts are not referenced via the graphic viewer.

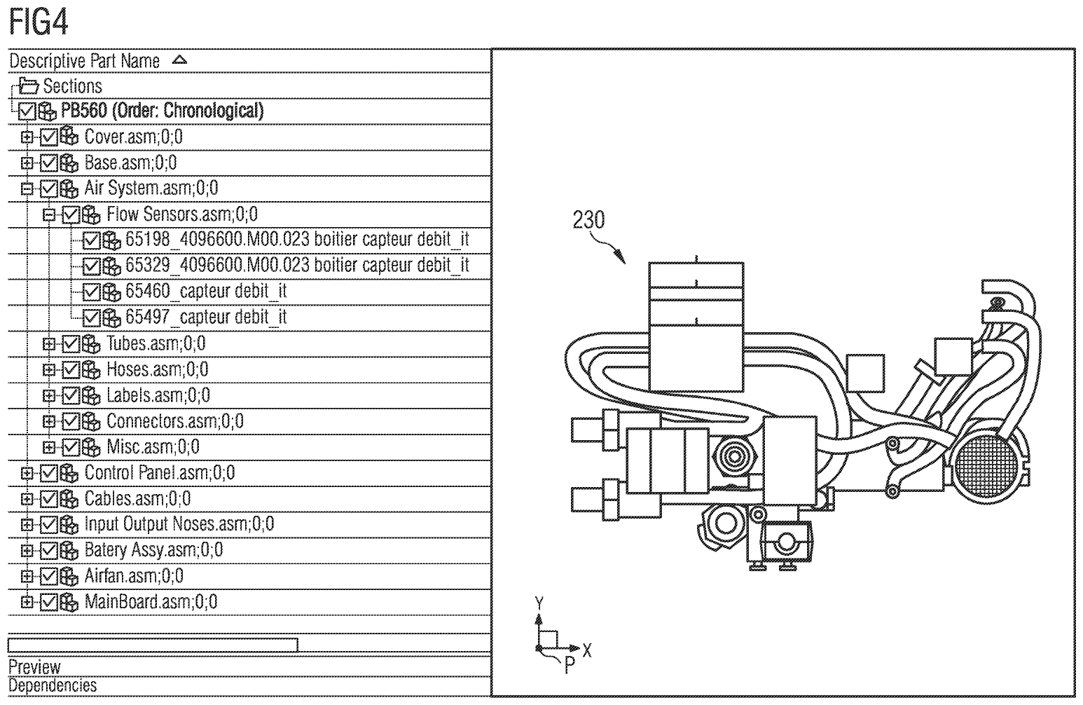

Assuming now that the user selects a specific sub-assembly via the graphic viewer, (air system 203 in the example considered), the graphic viewer will now present the complete sub-assembly 203 to the user as shown in FIG. 4. In the component list, the structure of air system 203 is expanded and, again, all constituent parts are marked as selected to indicate that the whole sub-assembly is referenced. The explosion of air system 203 (not shown) will take place in the same manner as that of the assembled ventilator 200, with reference to a user's viewpoint that can also be different from the one according to which explosion of assembled ventilator 200 has occurred: i.e., a new circular configuration of the components at the immediately lower hierarchical level is produced and, again, one or more of such components can be selected for further explosion, until a lowest hierarchical level of interest is reached.

For the sake of simplicity of the drawing, the different components of air system 203 indicated in the left-side portion of the Figure have not been specifically identified in the image appearing on graphic viewer. On the other hand, such an identification is not important for the understanding of the invention.

At any level, in an exploded configuration, either a single item or a plurality of items can be selected for further explosion. In case of selection of a plurality of items, the procedure described can be performed in parallel for each item selected.

Note that, even if in the above description it has been implicitly assumed that the explosion is made by immediately successive hierarchical levels, the level of explosion can be decided the user: namely, once he/she has at disposal an exploded view, he/she can select for explosion any component visible in the graphic viewer and not only parts at the immediately lower level. For instance, in the exploded view of FIG. 3, instead of selecting the air system, he/she could select any part thereof, e.g. the flow sensors or the tubes, having a composite, and hence decomposable, structure. The upper level components/sub-assemblies will appear faded in the left-side list, exactly alike the sub-assemblies other than the air system in FIG. 4.

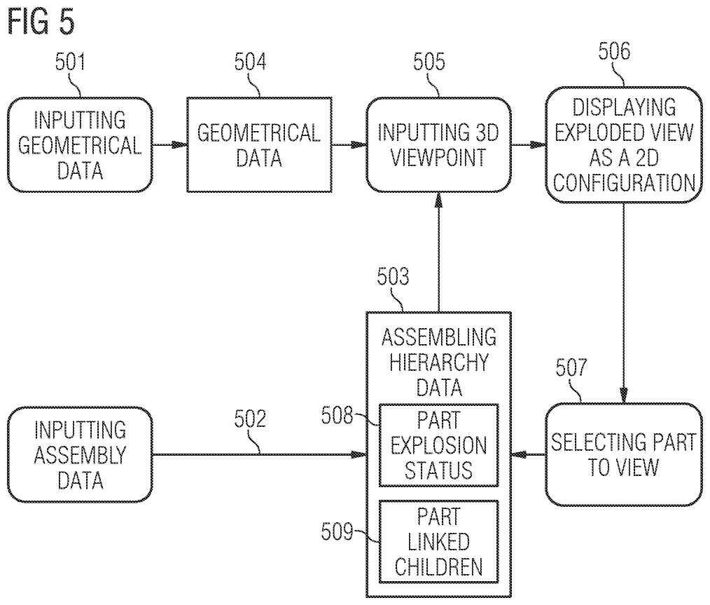

FIG. 5 illustrates a flowchart 500 of the method. Initially, in a preliminary phase, geometrical data and assembly data are input (steps 501, 502). As known to the skilled in the art, in CAD design a model file is first created, which includes the geometrical representations of the individual parts. Then an assembly file is created, and all model files that are to be included in that assembly are imported and ‘assembled’ in the 3D graphic software (step 503). This assembly file now includes references to the model files that include the geometrical representation of the parts, and the exact locations of these parts within the assembly context.

Once the geometrical data and the assembly data have been loaded, the method can be started. The first step is determining and inputting 3D viewpoint P (step 505) by using initially both geometrical data of the specific model to be worked and the assembly hierarchy data assembled in step 503.

Once 3D viewpoint P has been input, explosion of the model into a 2D configuration takes place (step 506, see also FIG. 3). Starting from the exploded view, the next step is the selection of a part to view (step 507). When doing so, the method stores the children linked to that part (step 508) and the explosion status of the part (step 509). At this point, a new viewpoint for the explosion of the part selected is determined and input, and the method continues to cycle through steps 505, 506, 507, 508, 509 until the final desired level of explosion is reached.

Note that, even if explosion results in a 2D configuration (circular shape), the user can still manipulate the configuration in a 3D environment, since a 3D point of view is selected for any subsequent explosion level.

One or more of the processor 102, the memory 108, and the program running on the processor 102 receive the inputs via one or more of the local system bus 106, the adapter 112, the network 130, the server 140, the interface 114, the I/O bus 116, the disk controller 120, the storage 126, and so on. Receiving, as used herein, can include retrieving from storage 126, receiving from another device or process, receiving via an interaction with a user, or otherwise.

Of course, those of skill in the art will recognize that, unless specifically indicated or required by the sequence of operations, certain steps in the processes described above may be omitted, performed concurrently or sequentially, or performed in a different order.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the mechanism of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims.

1-24. (canceled)

25. A method for generating, by a data processing system, an exploded layout of a CAD model in a 3D graphic environment, the method comprising steps of:
a) determining and inputting to the system a 3D user's viewpoint according to which explosion is to be performed;
b) identifying hierarchies in the model;
c) exploding the model, through a direct interaction with a model representation on a graphic viewer of the data processing system, into a 2D configuration of components;
d) individually selecting, on the graphic viewer, one or more components belonging to a lower hierarchical level for being in turn exploded to a further lower hierarchical level;
e) exploding the or each component selected at step d), through a direct interaction with the component representation on the graphic viewer, into a respective 2D configuration of components; and
f) repeating steps d), e) for components at further lower hierarchical levels visible as a result of each explosion step, until reaching a lowest hierarchical level of interest.

26. The method according to claim 25, which further comprises carrying out the step of exploding the model or one or more components of the model into a 2D configuration to result in a substantially circular image presented on a plane perpendicular to a vector originating from the viewpoint and making visible to the user all components at a concerned hierarchical level without overlap.

27. The method according to claim 25, which further comprises performing the step of determining and inputting to the system a 3D user's viewpoint for each component to be exploded.

28. The method according to claim 25, which further comprises carrying out each step of selecting one or more components on the graphic viewer for being exploded to result in starting a search mechanism leading to a nearest parent that was not exploded yet and in addressing the parent rather than the selected component.

29. The method according to claim 25, which further comprises saving a current status of the explosion at each exploding step.

30. The method according to claim 25, which further comprises, upon selecting more components to be exploded at step d), performing steps e) and f) in parallel for each component.

31. The method according to claim 25, which further comprises defining one or more components at any hierarchical level as end items for which a further explosion is not of interest.

32. The method according to claim 25, which further comprises having the user select the level of explosion.

33. A data processing system, comprising:
a processor; and
an accessible memory,
the data processing system being configured, in order to generate an exploded layout of a CAD model in a 3D graphic environment, to:
a) receive a user's viewpoint according to which explosion is to be performed;
b) identify hierarchies in the model;
c) explode the model, through a direct interaction with a model representation on a graphic viewer of the data processing system, into a 2D configuration of components;
d) receive a selection, made on the graphic viewer, of one or more of the components belonging to a lower hierarchical level for being in turn exploded to a further lower hierarchical level;
e) explode the or each component selected at item d), through a direct interaction with the component representation on said graphic viewer; into a respective 2D configuration of components; and
f) repeat items d), e) for components at successively lower hierarchical levels visible as a result of each explosion step, until reaching a lowest hierarchical level.

34. The data processing system according to claim 33, wherein the data processing system is configured, when exploding the model or one or more components of the model into a 2D configuration, to generate a substantially circular image on a plane perpendicular to a vector originating from said viewpoint, the image making visible to the user all components at a concerned hierarchical level without overlap.

35. The data processing system according to claim 33, wherein the data processing system is configured for receiving a 3D user's viewpoint for each component to be exploded.

36. The data processing system according to claim 33, wherein the data processing system is configured, when receiving the selection, made on the graphic viewer, of one or more components to be exploded, to start a search mechanism leading to a nearest parent that was not exploded yet and to address the nearest parent rather than the selected component.

37. The data processing system according to claim 33, wherein the data processing system is configured to save a current status of the explosion at each exploding step.

38. The data processing system according to claim 33, which further comprises, upon a selection of more components to be exploded at item d), the data processing system is configured to execute items e) and f) in parallel for each component.

39. The data processing system according to claim 33, wherein the data processing system is configured to further receive a selection of one or more components at any hierarchical level as end items for which explosion is not of interest.

40. The data processing system according to claim 33, wherein the data processing system is configured to receive from the user a selection of the explosion level.

41. A non-transitory computer-readable medium encoded with executable instructions that, when executed, cause one or more data processing systems to generate an exploded layout of a CAD model in a 3D graphic environment through steps of:
a) determining and inputting to the system a 3D user's viewpoint according to which explosion is to be performed;
b) identifying hierarchies in the model;
c) exploding the model, through a direct interaction with a model representation on a graphic viewer of the data processing system, into a 2D configuration of components;
d) individually selecting, on the graphic viewer, one or more components belonging to a lower hierarchical level for being in turn exploded to a further lower hierarchical level;
e) exploding the or each component selected at step d), through a direct interaction with the component representation on said graphic viewer, into a respective 2D configuration of components; and
f) repeating steps d), e) for components at further lower hierarchical levels visible as a result of each explosion step, until reaching a lowest hierarchical level of interest.

42. The non-transitory computer-readable medium according to claim 41, wherein the step of exploding the model or a component of the model into a 2D configuration results in a substantially circular image presented on a plane perpendicular to a vector originating from said viewpoint and making visible to the user all components at the concerned hierarchical level without overlap.

43. The non-transitory computer-readable medium according to claim 41, wherein the step of determining and inputting to the system a 3D user's viewpoint is performed for each component to be exploded.

44. The non-transitory computer-readable medium according to claim 41, wherein the step of receiving said selection of one or more components on the graphic viewer for being exploded results in starting a search mechanism leading to a nearest parent that was not exploded yet and in addressing the nearest parent rather than the selected component.

45. The non-transitory computer-readable medium according to claim 41, wherein a current status of the explosion is saved at each exploding step.

46. The non-transitory computer-readable medium according to claim 41, wherein, upon a selection of more components to be exploded at step d), steps e) and f) are performed in parallel for each component.

47. The non-transitory computer-readable medium according to claim 41, wherein the user selects the level of explosion.

48. The non-transitory computer-readable medium according to claim 41, wherein some components are defined as end items for which explosion is not of interest.
